(19) United States
(12) Patent Application Publication
(10) Pub. No.: US 2025/0215575 A1
(43) Pub. Date: Jul. 3, 2025

(54) ETCHING COMPOSITION, METHOD OF ETCHING METAL-CONTAINING LAYER USING THE SAME AND METHOD OF MANUFACTURING SEMICONDUCTOR DEVICE USING THE SAME

(71) Applicant: Samsung Electronics Co., Ltd., Suwon-si (KR)

(72) Inventors: Byungjoon KANG, Suwon-si (KR); Sungmin KIM, Suwon-si (KR); Insun PARK, Suwon-si (KR); Minjae SUNG, Suwon-si (KR); Sabyuk YANG, Suwon-si (KR); Jungmin OH, Suwon-si (KR); Kum Hee LEE, Suwon-si (KR); Cheol HAM, Suwon-si (KR); Kyuyoung HWANG, Suwon-si (KR)

(73) Assignee: Samsung Electronics Co., Ltd., Suwon-si (KR)

(21) Appl. No.: 18/999,924

(22) Filed: Dec. 23, 2024

(30) Foreign Application Priority Data
Dec. 28, 2023 (KR) 10-2023-0195609

(51) Int. Cl. C23F 1/26; H01L 21/3213

(52) U.S. Cl. CPC C23F 1/26; H01L 21/32134

(57) ABSTRACT

Provided are an etching composition including a hypervalent iodine-containing compound, a method of etching a metal-containing layer by using the same, and a method of manufacturing a semiconductor device by using the same.

### CROSS-REFERENCE TO RELATED APPLICATION

This application is based on and claims priority under 35 U.S.C. § 119 to Korean Patent Application No. 10-2023-0195609, filed on Dec. 28, 2023, in the Korean Intellectual Property Office, the disclosure of which is incorporated by reference herein in its entirety.

### BACKGROUND

### 1. Field

The disclosure relates to an etching composition, a method of etching a metal-containing layer by using the same, and a method of manufacturing a semiconductor device by using the same.

### 2. Description of the Related Art

To satisfy customers' demands for excellent performance and low price, improvement of integration and reliability of a semiconductor device has been required. As the degree of integration of a semiconductor device increases, damage to elements of the semiconductor device has a stronger influence on reliability and electrical characteristics of a semiconductor memory device during a process of manufacturing the semiconductor device. Particularly, various etching processes are conducted on certain layers (e.g., metal-containing layer) in semiconductor device manufacturing processes, and there is a continuing need for etching compositions capable of providing excellent etching rates, excellent etching selectivity to adjacent layers, absence of post-etch residue on surfaces, and excellent storage stability to effectively perform the etching processes.

### SUMMARY

Provided is an etching composition having excellent etching selectivity to a metal-containing layer that is a layer to be etched and capable of improving productivity and efficiency of an etching process.

Additional aspects will be set forth in part in the description which follows and, in part, will be apparent from the description, or may be learned by practice of the presented embodiments of the disclosure.

According to an aspect of the disclosure, an etching composition may include a hypervalent iodine-containing compound.

In some embodiments, the etching composition may further include an acid and water.

In some embodiments, the hypervalent iodine-containing compound may include trivalent iodine (iodine (III)) or pentavalent iodine (iodine (V)).

In some embodiments, the hypervalent iodine-containing compound may include iodine and one or more carbon atoms, wherein one of the carbon atoms may be bound to the iodine via a chemical bond.

In some embodiments, the hypervalent iodine-containing compound may include iodine and n ligands bound to the iodine, wherein at least one of the ligands may include a C₁-C₃₀ aromatic cyclic group.

In some embodiments, an amount of the hypervalent iodine-containing compound may be 0.005 wt % to 1 wt % based on 100 wt % of the etching composition.

In some embodiments, the acid may include a fluorine-based inorganic acid.

In some embodiments, an amount of the acid may be 0.0001 wt % to 20 wt % based on 100 wt % of the etching composition.

In some embodiments, the etching composition may further include a pH regulator.

In some embodiments, the etching composition may have a pH of 0 to 4.0.

According to another aspect of the disclosure, a method of etching a metal-containing layer may include preparing a substrate provided with a metal-containing layer, and performing an etching process on the metal-containing layer by using the etching composition to remove at least a portion of the metal-containing layer.

In some embodiments, the metal-containing layer may include indium (In), titanium (Ti), aluminum (AI), tungsten (W), lanthanum (La), scandium (Sc), gallium (Ga), zinc (Zn), hafnium (Hf), molybdenum (Mo), or any combination thereof.

In some embodiments, the metal-containing layer may include a first region and a second region,

In some embodiments, a second etching rate at which the composition etches the second region may be greater than a first etching rate at which the composition etches the first region, and the etching process may be performed by contacting at least a portion of the first region and at least a portion of the second region with the etching composition.

In some embodiments, the first region may include molybdenum, and the second region may include titanium nitride (TIN).

According to an embodiment of aspect of the disclosure, a method of manufacturing a semiconductor device may include preparing a substrate provided with a metal-containing layer, performing an etching process on the metal-containing layer by using the etching composition to remove at least one portion of the metal-containing layer, and performing a subsequent manufacturing process(es) to manufacture a semiconductor device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a process flowchart of a method of manufacturing a semiconductor device, according to an embodiment; and

FIGS. 2 and 3 are diagrams for schematically describing a method of etching a metal-containing layer, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Layer to be Etched

The layer to be etched may include a metal-containing layer.

Therefore, the etching composition may be used in an etching process and/or a CMP (chemical mechanical polishing) process of a metal-containing layer.

A metal included in the metal-containing layer may include an alkali metal (e.g., sodium (Na), potassium (K), rubidium (Rb), and cesium (Cs),), an alkali earth metal (e.g., beryllium (Be), magnesium (Mg), calcium (Ca), strontium (Sr), and barium (Ba)), a lanthanum group metal (e.g., lanthanum (La), europium (Eu), terbium (Tb), and ytterbium (Yb)), a transition metal (e.g., scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), and zinc (Zn)), a post transition metal (e.g., aluminum (AI), gallium (Ga), indium (In), thallium (TI), tin (Sn), and bismuth (Bi)), or any combination thereof.

According to an embodiment, the metal-containing layer may include indium (In), titanium (Ti), aluminum (AI), copper (Cu), tungsten (W), cobalt (Co), lanthanum (La), scandium (Sc), gallium (Ga), zinc (Zn), hafnium (Hf), molybdenum (Mo), or any combination thereof.

According to another embodiment, the metal-containing layer may include indium (In), titanium (Ti), aluminum (Al), tungsten (W), lanthanum (La), scandium (Sc), gallium (Ga), zinc (Zn), hafnium (Hf), molybdenum (Mo), or any combination thereof.

For example, the metal-containing layer may include aluminum, titanium, lanthanum, tungsten, molybdenum, or any combination thereof.

As another example, the metal-containing layer may include titanium.

As another example, the metal-containing layer may include titanium and aluminum.

As another example, the metal-containing layer may include tungsten.

As another example, the metal-containing layer may include molybdenum.

The metal-containing layer may include metal, metal nitride, metal oxide, metal oxynitride, or any combination thereof.

The metal-containing layer may include metal, metal nitride, metal oxide, metal oxynitride, or any combination thereof, and the metal and metals respectively included in the metal nitride, the metal oxide, and the metal oxynitride may include indium (In), titanium (Ti), aluminum (Al), lanthanum (La), scandium (Sc), gallium (Ga), zinc (Zn), hafnium (Hf), or any combination thereof.

The metal-containing layer may include metal nitride. The metal included in the metal nitride may include indium, titanium, aluminum, lanthanum, scandium, gallium, zinc, hafnium, or any combination thereof.

As another example, the metal-containing layer may include titanium nitride. The titanium nitride may further include indium, aluminum, lanthanum, scandium, gallium, hafnium, zinc, or any combination thereof. As another example, the metal-containing layer may include titanium nitride (TiN), titanium nitride further including aluminum (e.g., titanium/aluminum nitride or TiAlN), or titanium nitride further including lanthanum.

As another example, the metal-containing layer may include metal oxide. The metal included in the metal oxide may include titanium, aluminum, lanthanum, scandium, gallium, hafnium, or any combination thereof. For example, the metal-containing layer may include aluminum oxide (e.g., Al2O3), indium gallium zinc oxide (IGZO), and the like.

As another example, the metal-containing layer may include the metal and metal nitride.

According to another embodiment, the metal-containing film may include the metal nitride and the metal oxide.

As another example, the metal-containing layer may further include metalloid (e.g., boron (B), silicon (Si), germanium (Ge), arsenic (As), antimony (Sb), and tellurium (Te)), non-metal (e.g., nitrogen (N), phosphorus (P), oxygen (O), sulfur(S), and selenium (Se)), any combination thereof in addition to the metal.

For example, the metal-containing layer may further include silicon oxide.

The metal-containing layer may have a single-layer structure including (or consisting of) one or more substances, or a multilayer or pattern structure including different substances.

For example, the metal-containing layer may have i) a single-layer structure including (or consisting of) titanium nitride, ii) a double-layer or pattern structure including a first layer including (or consisting of) titanium nitride and a second layer including (or consisting of) titanium nitride further including aluminum, iii) a double-layer or pattern structure including a first layer including (or consisting of) titanium nitride and a second layer including (or consisting of) aluminum oxide, or iv) a double-layer or pattern structure including a first layer including (or consisting of) titanium nitride and a second layer including (or consisting of) molybdenum.

According to another embodiment, the metal-containing layer may include a first region and a second region, and a second etching rate at which the composition etches the second region may be greater than a first etching rate at which the composition etches the first region. During an etching process and/or polishing process of the metal-containing layer, at least a portion of the first region and at least a portion of the second region may be in contact with the etching composition, and the second region may be etched faster than the first region because the second etching rate is greater than the first etching rate.

For example, the first region may include metal, metal oxide (e.g., aluminum oxide), silicon oxide, or any combination thereof.

According to an embodiment, the first region may include molybdenum.

As another example, the second region may include metal nitride.

As another example, the second region may include i) titanium nitride, ii) titanium nitride further including indium, aluminum, lanthanum, scandium, gallium, zinc, hafnium, or any combination thereof, or iii) any combination thereof.

As another example, each of the first region and the second region may include i) titanium nitride, ii) titanium nitride further including indium, aluminum, lanthanum, scandium, gallium, zinc, hafnium, or any combination thereof, or iii) any combination thereof.

As another example, the first region may include aluminum, and the second region may not include aluminum.

As another example, the first region may include titanium nitride further including aluminum (e.g., titanium/aluminum nitride or TiAlN), and the second region may include titanium nitride (TiN).

As another example, the first region may include a titanium nitride layer further including aluminum (e.g., titanium/aluminum nitride layer or TiAlN layer), and the second region may include a titanium nitride layer (TiN layer).

As another example, the first region may be a titanium nitride layer further including aluminum (e.g., titanium/aluminum nitride layer or TiAlN layer), and the second region may be a titanium nitride layer (TiN layer).

As another example, the first region may include molybdenum, and the second region may not include molybdenum.

As another example, the first region may include molybdenum, and the second region may include titanium nitride (TiN).

As another example, the first region may include a molybdenum layer (Mo layer), and the second region may include a titanium nitride layer (TiN layer).

As another example, the first region may be a molybdenum layer (Mo layer), and the second region may be a titanium nitride layer (TiN layer).

Throughout the specification, the expression “etching a layer” may refer to removing at least a portion of a material constituting the layer.

### Etching Composition

The etching composition may include a hypervalent iodine-containing compound.

The etching composition may further include an acid, a pH regulator, a selective etching inhibitor, a selective etching accelerator, a solvent, water, or any combination thereof in addition to the hypervalent iodine-containing compound.

For example, the etching composition may further include an acid and water in addition to the hypervalent iodine-containing compound. In the case where the etching composition further includes an acid and water as well as the hypervalent iodine-containing compound, the hypervalent iodine-containing compound may act as an oxidant.

As another example, the etching composition may further include a pH regulator in addition to the hypervalent iodine-containing compound.

As another example, the etching composition may further include an acid, a pH regulator, and water in addition to the hypervalent iodine-containing compound.

The etching composition may be used in an etching process and/or CMP process of the layer to be etched described in the specification, e.g., the metal-containing layer.

### Hypervalent Iodine-containing Compound

The hypervalent iodine-containing compound may serve to etch the metal-containing layer. For example, the hypervalent iodine-containing compound may serve to remove titanium atoms from the metal-containing layer. As another example, the hypervalent iodine-containing compound may act as an oxidizer.

According to an embodiment, the hypervalent iodine-containing compound may include trivalent iodine (iodine (III)) or pentavalent iodine (iodine (V)).

According to another embodiment, the hypervalent iodine-containing compound may include iodine and one or more carbon atoms, wherein one of the carbon atoms may be bound to the iodine via a chemical bond.

According to another embodiment, the hypervalent iodine-containing compound may include iodine and n ligands bound to the iodine, wherein the n may be 1, 2, 3, 4, 5, or 6 (e.g., 1, 2, or 3).

According to another embodiment, among the n ligands, at least one ligand may be an organic ligand. For example, at least one ligand of the n ligands may include a C₁-C₃₀ aromatic cyclic group (e.g., benzene group, naphthalene group, pyridine group, and pyrimidine group).

According to another embodiment, each of the n ligands may be a monodentate ligand or a bidentate ligand.

According to another embodiment, the hypervalent iodine-containing compound may be a compound represented by Formula 1 below, a compound represented by Formula 2 below, a compound represented by Formula 3 below, a compound represented by Formula 4 below, or any combination thereof.

I(L₁)(L₂)(L₃) <Formula 1>

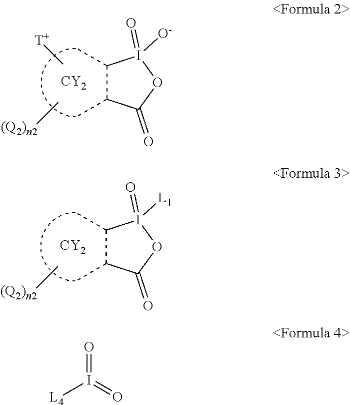

In Formulae 1 to 4,
L₁, L₂, L₃, and L₄ are each independently a ligand bound to iodine of Formulae 1 to 4,
L₁ and L₂ are each independently *—OH, *—SH, *—O(Q₁), *—S(Q₁), *—O-S(═O)₂-Q₁, *—O—C(═O)-Q₁, *—S—C(═O)-Q₁, *—O—C(═S)-Q₁, *—S—C (═S)-Q₁, *—S(═O)₂-Q₁, *—C(═O)-Q₁, *—C(═S)-Q₁, *—S(═O)₂—O-Q₁, *—C(═O)—O-Q₁, or *—C(═S)—O-Q₁,
L₃ and L₄ are each independently a C₃-C₃₀ carbocyclic group or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N (CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, *—SO₃(Q₁₁), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof,
ring CY₂ is a C₃-C₃₀ carbocyclic group or a C₁-C₃₀ heterocyclic group,

Q₁ and Q₂ are each independently:
hydrogen, deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, or *—SO₃(Q₁₁), or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, *—SO₃(Q₁₁), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof,

n2 is an integer from 0 to 10,

Q₁₁ is hydrogen or alkali metal,

T⁺ is [N(Q₂₁)(Q₂₂)(Q₂₃)]⁺, Q₂₁ to Q₂₃ are as described above with reference to Q_{1,}and

* is a binding site with an adjacent atom. In other words, Q₂₁ to Q₂₃ independently may be any element or group described above for Q₁.

For example, in Formula 1, L₂ may be *—O—S(═O)₂-Q₁, *—O—C(═O)-Q₁, *—S—C(═O)-Q₁, *—O—C(═S)-Q₁, *—S—C(═S)-Q₁, *—S(═O)₂-Q₁, *—C(═O)-Q₁, *—C(═S)-Q₁, *—S(═O)₂—O-Q₁, *—C(═O)—O-Q₁, or *—C(═S)—O-Q₁. For example, in Formula 1, L₂ may be *—O-S(═O)₂-Q₁ or *—O—C(═O)-Q₁.

According to an embodiment, in Formulae 1 and 3, L₁ may be *—OH, *—O—S(═O)₂-Q₁, or *—O—C(═O)-Q₁.

According to another embodiment, in Formula 1, L₁ and L₂ may be identical to each other.

According to another embodiment, in Formula 1, L₁ and L₂ may be different from each other.

According to another embodiment, in Formula 1, a bond between iodine and the ligand Ls may be an iodine-carbon bond.

According to another embodiment, Q₁ may be a C₁-C₁₀ alkyl group, a C₁-C₁₀ alkoxy group, a phenyl group, a naphthyl group, or a pyridinyl group, each unsubstituted or substituted with deuterium, *—F, a C₁-C₁₀ alkyl group, a C₁-C₁₀ alkoxy group, a phenyl group, a naphthyl group, a pyridinyl group, or any combination thereof.

According to another embodiment, in Formula 1, L₃ may be a phenyl group, a naphthyl group, or a pyridinyl group, each unsubstituted or substituted with deuterium, *—F, a C₁-C₁₀ alkyl group, a C₁-C₁₀ alkoxy group, a phenyl group, a naphthyl group, a pyridinyl group, or any combination thereof.

According to another embodiment, in Formulae 2 and 3, ring CY₂ may be a benzene group, a naphthalene group, a phenanthrene group, a pyridine group, a pyrimidine group, a pyrazine group, or a pyridazine group.

According to another embodiment, in Formulae 2 and 3, Q₂ may be hydrogen, *—C(═O)—OH, or *—SO₃(Q₁₁).

According to another embodiment, in Formulae 2 and 3, n2 may be 0, 1 or 2.

According to another embodiment, in Formula 4, L₄ may be a phenyl group, a naphthyl group, or a pyridinyl group, each unsubstituted or substituted with deuterium, *—F, *—SO₃ (Q₁₁), a C₁-C₁₀ alkyl group, a C₁-C₁₀ alkoxy group, a phenyl group, a naphthyl group, a pyridinyl group, or any combination thereof.

According to another embodiment, Q₁₁ may be hydrogen, Li, Na, K, Rb, or Cs.

According to another embodiment, in Formula 2, T⁺ may be [N(Q₂₁)(Q₂₂)(Q₂₃)]⁺, and Q₂₁ to Q₂₃ may be each independently a C₁-C₁₀ alkyl group, a C₁-C₁₀ alkoxy group, a phenyl group, a naphthyl group, or a pyridinyl group, each unsubstituted or substituted with deuterium, *—F, a C₁-C₁₀ alkyl group, a C₁-C₁₀ alkoxy group, or any combination thereof.

According to another embodiment, the compound represented by Formula 2 may be a compound represented by Formula 2A below, and the compound represented by Formula 3 may be a compound represented by Formula 3A below.

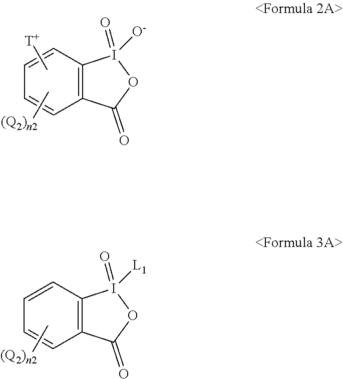

In Formulae 2A and 3A, L₁, Q₂, and T⁺ are as described above, n2 of Formula 2A is an integer from 0 to 3, and n2 of Formula 3A is an integer from 0 to 4.

According to another embodiment, the hypervalent iodine-containing compound may include a compound represented by Formula 1.

According to another embodiment, the hypervalent iodine-containing compound may be one of Compounds 1 to 10 below:

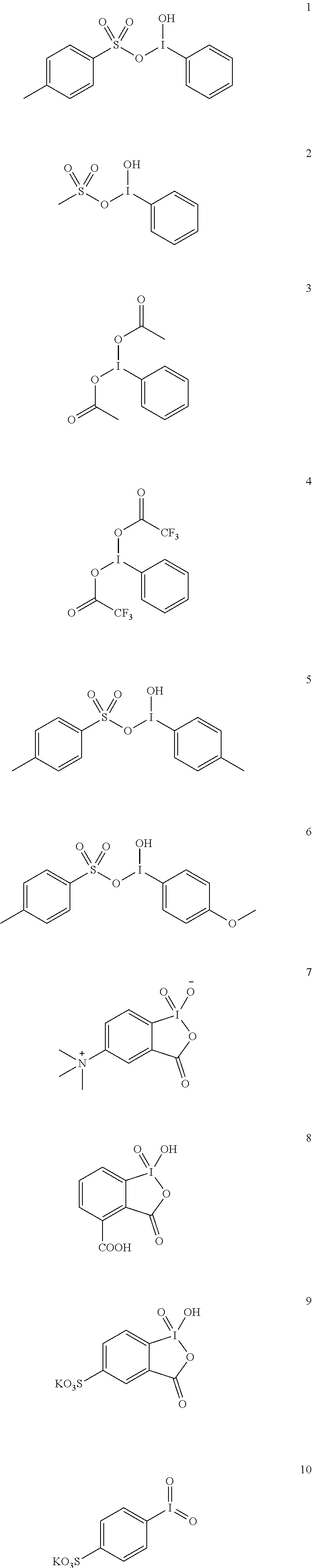

Compound 1 is [hydroxy(tosyloxy)iodo]benzene (HTIB), Compound 2 is [hydroxy(mesyloxy)iodo]benzene (HMIB), Compound 3 is (diacetoxyiodo) benzene (PIDA), Compound 4 is [bis(trifluoroacetoxy)iodo]benzene (PIFA), Compound 5 is [hydroxy(tosyloxy)iodo](methyl)benzene (HTI(tolyl)), Compound 6 is [hydroxy(tosyloxy)iodo]anisole(HTI(anisole)), Compound 7 is (5-trimethylammonio-1,3-dioxo-1,3-dihydro-1λ⁵-benzo[d][1,2]iodoxol-1-ol anion) (AIBX), Compound 8 is 1-hydroxy-1,3-dioxo-1,3-dihydro-1λ⁵-benzo[d][1,2] iodoxole-4-carboxylic acid (mIBX), Compound 9 is potassium 1-hydroxy-1,3-dioxo-1,3-dihydro-1λ⁵-benzo[d][1,2]iodoxole-5-sulfonate (IBX-SO₃K), and Compound 10 is potassium 4-iodylbenzenesulfonate (PIBS).

An amount of the hypervalent iodine-containing compound may be about 0.005 wt % to about 1 wt %, about 0.005 wt % to about 0.5 wt %, about 0.005 wt % to about 0.1 wt %, about 0.005 wt % to about 0.05 wt %, or about 0.005 wt % to about 0.01 wt %, based on 100 wt % of the etching composition. When the amount of the hypervalent iodine-containing compound is within the ranges described above, etching selectivity may further be improved.

In the case where the etching composition includes the hypervalent iodine-containing compound, excellent etching selectivity to the metal-containing layer (e.g., etching selectivity capable of selectively and predominantly removing an area containing titanium nitride between the area containing titanium nitride and the area containing molybdenum) may be maintained.

In addition, in the case where the etching composition includes the hypervalent iodine-containing compound, etching rate deviation and etching selectivity deviation may be reduced over the entire area of the metal-containing layer, and thus excellent etching uniformity may be obtained. By obtaining etching uniformity as described above, insufficient etching occurring in some areas of a substrate in a large-area substrate may be limited and/or prevented, and thus accuracy of the etching process may be improved.

That is, in the case where the etching composition includes the hypervalent iodine-containing compound, “both” excellent etching selectivity and excellent etching uniformity may be obtained. Therefore, by using the etching composition, efficiency, accuracy, and productivity of the etching process may be improved.

### Acid

The acid may serve to etch the metal-containing layer together with the hypervalent iodine-containing compound.

The acid may include a nitric acid-based inorganic acid, a sulfuric acid-based inorganic acid, a phosphoric acid-based inorganic acid, a chlorine-based inorganic acid, a fluorine-based inorganic acid, or any combination thereof.

According to an embodiment, the acid may include a fluorine-based inorganic acid.

For example, the fluorine-based inorganic acid may include hydrofluoric acid (HF), tetrafluoroboric acid, hexafluorosilicic acid, H₂ZrF₆, H₂TiF₆, HPF₆, or any combination thereof.

An amount (weight) of the acid may be, for example, about 0.0001 wt % to about 20 wt %, about 0.0001 wt % to about 10 wt %, about 0.0001 wt % to about 5 wt %, about 0.0001 wt % to about 1 wt %, about 0.001 wt % to about 20 wt %, about 0.001 wt % to about 10 wt %, about 0.001 wt % to about 5 wt %, or about 0.001 wt % to about 1 wt %, based on 100 wt % of the etching composition. When the amount of the acid satisfies the ranges described above, etching performance of the etching composition may be improved with the pH of the etching composition maintained in an appropriate range.

According to another embodiment, the acid may be an organic acid, such as acetic acid, tartaric acid, and benzoic acid.

pH Regulator

The pH regulator serves to maintain the pH of the etching composition in an appropriate range.

The pH regulator may be any known materials suitable for a pH regulator in an etching composition.

According to an embodiment, the pH regulator may be selected from water-soluble substances and may include methylsulfonic acid (MSA), ethylsulfonic acid, phosphoric acid, sulfuric acid, hydrogen chloride, or any combination thereof.

The etching composition as described above may have a pH of 0 to about 8.0, 0 to about 7.0, 0 to about 6.0, 0 to about 5.0, 0 to about 4.0, 0 to about 3.0, about 1.0 to about 8.0, about 1.0 to about 7.0, about 1.0 to about 6.0, about 1.0 to about 5.0, about 1.0 to about 4.0, about 1.0 to about 3.0, about 2.0 to about 8.0, about 2.0 to about 7.0, about 2.0 to about 6.0, about 2.0 to about 5.0, about 2.0 to about 4.0, or about 2.0 to about 3.0.

For example, the etching composition may have a pH of 0 to about 4.0, 0 to about 3.5, 0 to about 3.0, 0 to about 2.0, about 0.5 to about 4.0, about 0.5 to about 3.5, about 0.5 to about 3.0, or about 0.5 to about 2.0. When the etching composition has the pH in the range described above, interactions between metal atoms of the metal-containing layer and the hypervalent iodine-containing compound may occur more smoothly.

According to an embodiment, the etching composition may be used in an etching process and/or CMP process of the metal-containing layer. The metal-containing layer is as described above.

Alternatively, the etching composition may be used as an etching by-product remover, a post-etch by-product remover, an ashing by-product remover, a cleaning composition, a photoresist (PR) remover, an etching composition for a packing process, a cleaner for a packaging process, a wafer adhesive remover, an etchant, a post-etch residue stripper, an ash residue cleaner, a photoresist (PR) residue stripper, a CMP cleaner, or a post-CMP cleaner.

### Method of Etching Metal-containing Layer and Method of Manufacturing Semiconductor Device

The metal-containing layer may be effectively etched by using the etching composition as described above.

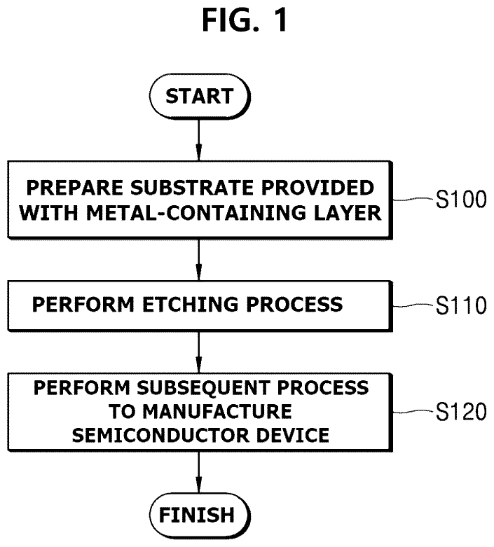

Referring to FIG. 1, the method of etching a metal-containing layer according to an embodiment may include: preparing a substrate provided with a metal-containing layer S100; and performing an etching process on the metal-containing layer using the etching composition S110 to remove at least a portion of the metal-containing layer.

The metal-containing layer is as described above.

For example, the metal-containing layer may include indium (In), titanium (Ti), aluminum (AI), tungsten (W), lanthanum (La), scandium (Sc), gallium (Ga), zinc (Zn), hafnium (Hf), molybdenum (Mo), or any combination thereof.

As another example, the metal-containing layer may include metal, metal nitride, metal oxide, metal oxynitride, or any combination thereof.

By including the hypervalent iodine-containing compound as described above, the etching composition may have “both” excellent etching selectivity to the metal-containing layer and excellent etching uniformity over the entire area of the metal-containing layer, thereby improving efficiency, accuracy, and productivity of the etching process. Therefore, a semiconductor device with excellent performance may be manufactured by using the metal-containing layer etching process using the etching composition as described above.

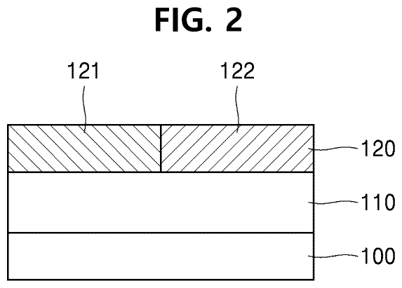

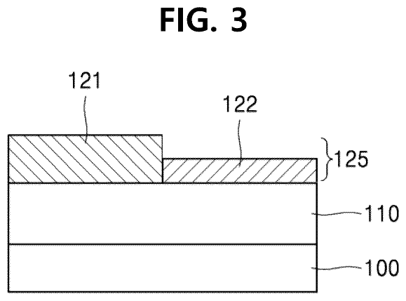

FIGS. 2 and 3 are diagrams for schematically describing a method of etching a metal-containing layer according to an embodiment.

Referring to FIG. 2, a substrate 100 provided with a metal-containing layer 120 is provided. An intermediate layer 110 may be disposed between the substrate 100 and the metal-containing layer 120. Although not shown in FIG. 2, circuitry elements (e.g., transistor gates, metal lines, impurity regions, and semiconductor layers) may be located in the substrate 100, on the substrate 100, between the substrate 100 and the intermediate layer 110, and/or the like. According to an embodiment, the metal-containing layer 120 may be directly located on the substrate 100 and the intermediate layer 110 may be omitted.

The metal-containing layer 120 may include a first region 121 and a second region 122. An etching rate at which the composition etches the second region 122 may be greater than an etching rate at which the composition etches the first region 121.

Referring to FIG. 3, a pattern 125 of the metal-containing layer may be formed by respectively etching at least a portion of the first region 121 and at least a portion of the second region 122 by using the etching composition in the etching process of the metal-containing layer 120. The etching process may be performed by contacting at least a portion of the first region 121 and at least a portion of the second region 122 with the etching composition.

The etching composition may respectively etch at least a portion of the first region 121 and at least a portion of the second region 122. In FIG. 3, the pattern 125 of the metal-containing layer formed after etching may include some portions or more of the second region 122, but various modifications may be possible. If required, the etching process may be performed to completely remove the second region 122 from the pattern 125 of the metal-containing layer.

According to another embodiment, the first region 121 may include metal oxide (e.g., aluminum oxide), silicon oxide, tungsten, or any combination thereof.

According to another embodiment, the second region 122 may include titanium nitride.

According to another embodiment, the second region 122 may include i) titanium nitride, ii) titanium nitride further including indium, aluminum, lanthanum, scandium, gallium, zinc, hafnium, or any combination thereof, or iii) any combination thereof.

According to another embodiment, each of the first region 121 and the second region 122 may include i) titanium nitride, ii) titanium nitride further including indium, aluminum, lanthanum, scandium, gallium, zinc, hafnium, or any combination thereof, or iii) any combination thereof.

According to another embodiment, the first region 121 may include molybdenum, and the second region 122 may not include molybdenum.

According to another embodiment, the first region 121 may include molybdenum, and the second region 122 may include titanium nitride (TiN).

According to another embodiment, the first region 121 may be a molybdenum (Mo) layer, and the second region 122 may be a titanium nitride (TiN) layer.

According to another embodiment, an etching rate ratio of the second region 122 to the first region 121 by the etching composition may be about 3 to about 30, about 3 to about 20, about 3 to about 15, or about 3 to about 10. The etching rate ratio of the second region 122 to the first region 121 may be obtained by dividing the second etching rate at which the composition etches the second region 122 by the first etching rate at which the composition etches the first region 121. In the case where the etching rate ratio of the second region 122 to the first region 121 by the etching composition satisfies the ranges described above, efficiency and productivity of the etching process may be improved.

According to another embodiment, the first region 121 may include molybdenum, the second region 122 may include titanium nitride, and the etching rate ratio of the second region 122 to the first region 121 by the etching composition (hereinafter, referred to as “R(TiN/Mo)” may be about 3 to about 30, about 3 to about 20, about 3 to about 15, or about 3 to about 10. The R(TiN/Mo) may be obtained by dividing the etching rate at which the composition etches the second region 122 including titanium nitride by the etching rate at which the composition etches the first region 121 including molybdenum.

Referring to FIG. 1, a method of manufacturing a semiconductor device according to an embodiment may include: preparing a substrate provided with a metal-containing layer S100; performing an etching process on the metal-containing layer by using the etching composition S110 to remove at least a portion of the metal-containing layer; and performing a subsequent manufacturing process(es) S120 to manufacture a semiconductor device.

Hereinafter, one or more example embodiments will be described in further detail with reference to the following examples and comparative examples. These examples and comparative examples are not intended to limit the scope of inventive concepts.

Examples 1 and 2 and Comparative Examples 1A, 1B, 2A, 2B, 3A, and 3B

0.05 wt % of an acid, 0.6 wt % of a pH regulator, and each of oxidants shown in Table 1 in an amount described therein were mixed to prepare etching compositions of

Examples 1 and 2 and Comparative Examples 1A, 1B, 2A, 2B, 3A, and 3B. The acid was hydrofluoric acid (HF), and the pH regulator was methylsulfonic acid (MSA). The balance of each etching composition was water (deionized water).

### Evaluation Example 1

After the etching composition of Example 1 was added to two beakers and heated to 70° C., a titanium nitride layer (TiN layer) sample with a size of 1 cm×1 cm and a molybdenum layer (Mo layer) sample with a size of 1 cm×1 cm were immersed respectively in the etching compositions of the beakers for 5 minutes. Then, thicknesses of the titanium nitride layer and the molybdenum layer were measured by using an ellipsometer (M-2000, J. A. Woolam), a 4 point probe, and X-ray fluorescence (XRF) to evaluate an etching rate (Å/min) of the TiN layer and an etching rate (Å/min) of the Mo layer by the etching composition of Example 1. Subsequently, the R(TiN/Mo) by the etching composition of Example 1 was evaluated by dividing the etching rate of the titanium nitride layer by the etching rate of the molybdenum layer, and the results are shown in Table 1.

This test was repeated by using each of the etching compositions of Example 2 and Comparative Examples 1A, 1B, 2A, 2B, 3A, and 3B, and the results are shown in Table 1.

TABLE 1

| | | | | | Etching | Etching | |
|---|---|---|---|---|---|---|---|
| | | | | | rate of | rate of | |
| | Oxidant | | | | TiN | Mo | R |
| | | Amount (wt %) | | | layer | layer | (TiN/ |
| | Substance | ppm | wt % | pH | (Å/min) | (Å/min) | Mo) |
| Example 1 | 1 | 100 | 0.01 | 1 | 37.8 | 6.6 | 5.7 |
| Example 2 | 2 | 100 | 0.01 | 1 | 25.1 | 4.6 | 5.5 |
| Comparative | periodic acid | 10 | 0.001 | 1 | 90 | 20 | 4.5 |
| Example 1A | (HIO₄) | | | | | | |
| Comparative | periodic acid | 100 | 0.01 | 1 | 12.1 | 52.5 | 0.2 |
| Example 1B | (HIO₄) | | | | | | |
| Comparative | ammonium | 10 | 0.001 | 1 | 82.8 | 16.2 | 5.1 |
| Example 2A | iodate | | | | | | |
| | (NH₄IO₃) | | | | | | |
| Comparative | ammonium | 100 | 0.01 | 1 | 17 | 38 | 0.45 |
| Example 2B | iodate | | | | | | |
| | (NH₄IO₃) | | | | | | |
| Comparative | H₂O₂ | 10 | 0.001 | 1 | 40 | >100 | <1 |
| Example 3A | | | | | | | |
| Comparative | H₂O₂ | 100 | 0.01 | 1 | >100 | >200 | <1 |
| Example 3B | | | | | | | |

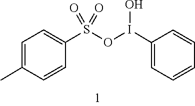 [SMILES: Cc1ccc(S(=O)(=O)OI(O)c2ccccc2)cc1]

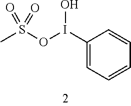

Referring to Table 1, it was confirmed that the etching compositions of Comparative Example 1B, 2B, 3A, and 3B had R(TiN/Mo) ratios of not more than 1, indicating poor etching selectivity (etching selectivity selectively and predominantly removing the titanium nitride layer between the TiN layer and the Mo layer).

Subsequently, Evaluation Example 2 was conducted to evaluate etching uniformity by the etching compositions of Example 1 and Comparative Example 1A.

### Evaluation Example 2

After the etching composition of Example 1 was added to three beakers and heated to 70° C., i) a titanium nitride layer (TiN layer) sample with a size of 1 cm×1 cm and a molybdenum layer (Mo layer) sample with a size of 1 cm×1 cm were simultaneously immersed in the etching composition of the first beaker for 5 minutes, ii) a titanium nitride layer (TiN layer) sample with a size of 1 cm×2 cm and a molybdenum layer (Mo layer) sample with a size of 1 cm×2 cm were simultaneously immersed in the etching composition of the second beaker for 5 minutes, and iii) a titanium nitride layer (TiN layer) sample with a size of 2 cm×2 cm and a molybdenum layer (Mo layer) sample with a size of 2 cm×2 cm were simultaneously immersed in the etching composition of the third beaker for 5 minutes. Then, thicknesses of the samples were measured by using an ellipsometer (M-2000, J. A. Woolam), a 4 point probe, and X-ray fluorescence (XRF) to evaluate etching rates (A/min) of the TiN layers and etching rates (A/min) of the Mo layers by the etching composition of Example 1, and the results are shown in Table 2.

For comparison, a relative value (%) of the etching rate of the TiN layer with a size of 1 cm×2 cm and a relative value (%) of the etching rate of the TiN layer with a size of 2 cm×2 cm were calculated as values relative to the etching rate of the TiN layer with a size of 1 cm×1 cm, and a relative value (%) of the etching rate of the Mo layer with a size of 1 cm×2 cm and a relative value (%) of the etching rate of the Mo layer with a size of 2 cm×2 cm were calculated as values relative to the etching rate of the Mo layer with a size of 1 cm×1 cm. The results are shown in Table 2.

Subsequently, a R(TiN/Mo) of the sample with a size of 1 cm×1 cm by the etching composition of Example 1, a R(TiN/Mo) of the sample with a size of 1 cm×2 cm by the etching composition of Example 1, and a R(TiN/Mo) of the sample with a size of 2 cm×2 cm by the etching composition of Example 1 were evaluated by dividing the etching rate of the TiN layer by the etching rate of the Mo layer for samples with the same size. The results are shown in Table 2.

For comparison, a relative value (%) of the R (TiN/Mo) of the 1 cm×2 cm sample, and a relative value (%) of the R(TIN/Mo) of the 2 cm×2 cm sample were calculated as values relative to the R(TiN/Mo) of the 1 cm×1 cm sample (100%). The results are shown in Table 2.

This test was repeated by using the etching composition of Comparative Example 1A, and the results are shown in Table 2.

TABLE 2

| | | Etching composition No. | | | |
|---|---|---|---|---|---|
| | | Example 1 | | Comparative Example 1A | |
| | | Oxidant | | | |
| | | 1 (0.01 wt %) | | HIO₄ (0.001 wt %) | |
| | | Measured | Relative | Measured | Relative |
| Sample | | value | value | value | value |
| size | | (Å/min) | (%) | (Å/min) | (%) |
| 1 cm × | Etching rate | 28.5 | 100 | 80.8 | 100 |
| 1 cm | of TiN layer | | | | |
| (Refer- | Etching rate | 3.6 | 100 | 21.8 | 100 |
| ence | of Mo layer | | | | |
| sample) | R (TiN/Mo) | 7.9 | 100 | 3.7 | 100 |
| 1 cm × | Etching rate | 32.0 | 112 | 46.0 | 57 |
| 2 cm | of TiN layer | | | | |
| | Etching rate | 4.4 | 122 | 8.9 | 41 |
| | of Mo layer | | | | |
| | R (TiN/Mo) | 7.3 | 92 | 5.2 | 141 |
| 2 cm × | Etching rate | 25.2 | 88 | 27.3 | 34 |
| 2 cm | of TiN layer | | | | |
| | Etching rate | 3 | 83 | 6.5 | 30 |
| | of Mo layer | | | | |
| | R (TiN/Mo) | 8.4 | 106 | 4.2 | 114 |

Referring to Table 2, although the size of the sample increased, it was confirmed that the etching rates of 88% or more were maintained in the case of the TiN layer and the etching rates of 83% or more were maintained in the case of the Mo layer by the etching composition of Example 1. However, in the case of the etching composition of Comparative Example 1A, it was confirmed that the etching rate of the TiN layer and the etching rate of the Mo layer decreased to levels of “not more than 57%” and “not more than 41%”, respectively, as the sample size increased.

Subsequently, based on Table 2, averages and standard deviations of the R (TIN/Mo) relative values of the three types of samples by each of the etching compositions of Example 1 and Comparative Example 1A were calculated and shown in Table 3.

TABLE 3

| | Etching composition No. | | | |
|---|---|---|---|---|
| | Example 1 | | Comparative Example 1A | |
| | Oxidant | | | |
| | 1 (0.01 wt %) | | HIO₄ (0.001 wt %) | |
| | | Standard | | Standard |
| | Average | deviation | Average | deviation |
| R (TiN/Mo) relative | 99.3 | 5.7 | 118.3 | 17.0 |
| value (%) | | | | |

Referring to Table 3, it was confirmed that the standard deviation of the R(TiN/Mo) relative values of the etching composition of Comparative Example 1A for the three types of samples was about three times or more than the standard deviation of the R(TIN/Mo) relative values of the etching composition of Examples 1. That is, it was confirmed that the R(TiN/Mo) of the etching composition of Example 1 varies less than the etching composition of Comparative Example 1A although the sample size increases, and therefore it was confirmed that the etching composition of Example 1 had excellent etching uniformity.

Because the etching composition has both excellent etching selectivity and excellent etching uniformity for the metal-containing layer that is a layer to be etched, efficiency, accuracy, and productivity of the etching process may be improved thereby. Therefore, effective etching processes and/or chemical mechanical polishing processes may be performed on layers to be etched by using the etching composition. Therefore, semiconductor devices manufactured by etching metal-containing layers by using the etching composition may have excellent performance.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An etching composition comprising:
a hypervalent iodine-containing compound.

2. The etching composition of claim 1, further comprising:
an acid; and
water.

3. The etching composition of claim 1,
wherein the hypervalent iodine-containing compound comprises trivalent iodine (iodine (III)) or pentavalent iodine (iodine (V)).

4. The etching composition of claim 1,
wherein the hypervalent iodine-containing compound comprises iodine and one or more carbon atoms, and
wherein one of the carbon atoms is bound to the iodine via a chemical bond.

5. The etching composition of claim 1,
wherein the hypervalent iodine-containing compound comprises iodine and n ligands bound to the iodine, and
wherein at least one of the ligands comprises a C₁-C₃₀ aromatic cyclic group.

6. The etching composition of claim 1,
wherein the hypervalent iodine-containing compound is a compound represented by Formula 1 below, a compound represented by Formula 2 below, a compound represented by Formula 3 below, a compound represented by Formula 4 below, or a combination thereof:
I(L₁)(L₂)(L₃) <Formula 1> 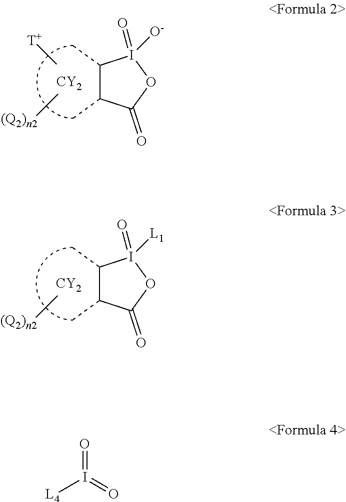
wherein in Formulae 1 to 4,
L₁, L₂, L₃, and L₄ are each independently a ligand bound to iodine of one of Formulae 1 to 4,
L₁ and L₂ are each independently *—OH, *—SH, *—O(Q₁), *—S(Q₁), *—O—S(═O)₂-Q₁, *—O—C(═O)-Q₁, *—S—C(═O)-Q₁, *—O—C(═S)-Q₁, *—S—C(═S)-Q₁, *—S(═O)₂-Q₁, *—C(═O)-Q₁, *—C(═S)-Q₁, *—S (═O)₂-O-Q₁, *—C(═O)—O-Q₁, or *—C(═S)-O-Q_{1,}
L₃ and L₄ are each independently a C₃-C₃₀ carbocyclic group or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N (CH₃)₂, *—NH—C(═O)—NH₂, *—NH—C(═O)—NH(CH₃), *—NH—C(═O)—N(CH₃)₂, *—NH₂, *—NH(CH₃), *—NCH₃)₂, *—SO₃(Q₁₁), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
ring CY₂ is a C₃-C₃₀ carbocyclic group or a C₁-C₃₀ heterocyclic group,
T⁺ is [N(Q₂₁) (Q₂₂) (Q₂₃)]⁺
Q₁, Q₂, Q₂₁, Q₂₂, and Q₂₃ are each independently:
hydrogen, deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH (CH₃), *—NH—C(═O)—N(CH₃)₂, *—NH₂, *—NH(CH₃), *—N(CH₃)₂, or *—SO₃ (Q₁₁); or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)-NH₂, *—NH—C(═O)—NH(CH₃), *—NH—C(═O)—N(CH₃)₂, *—NH₂, *—NH (CH₃), *—N(CH₃)₂, *—SO₃ (Q₁₁), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
n2 is an integer from 0 to 10,
Q₁₁ is hydrogen or an alkali metal, and
* is a binding site with an adjacent atom.

7. The etching composition of claim 6,
wherein L₂ is *—O—S(═O)₂-Q₁, *—O—C(═O)-Q₁, *—S-C(═O)-Q₁, *—O—C(═S)-Q₁, *—S-C(═S)-Q₁, *—S(═O)₂-Q₁, *—C(═O)-Q₁, *—C (═S)-Q₁, *—S(═O)₂-O-Q₁, *—C(═O)—O-Q₁, or *—C(═S)—O-Q₁.

8. The etching composition of claim 6,
wherein Q₁ is a C₁-C₁₀ alkyl group, a C₁-C₁₀ alkoxy group, a phenyl group, a naphthyl group, or a pyridinyl group, each unsubstituted or substituted with deuterium, *—F, a C₁-C₁₀ alkyl group, a C₁-C₁₀ alkoxy group, a phenyl group, a naphthyl group, a pyridinyl group, or a combination thereof,
L₃ is a phenyl group, a naphthyl group, or a pyridinyl group, each unsubstituted or substituted with deuterium, *—F, a C₁-C₁₀ alkyl group, a C₁-C₁₀ alkoxy group, a phenyl group, a naphthyl group, a pyridinyl group, or a combination thereof,
Q₂ is hydrogen, *—C(═O)—OH, or *—SO₃(Q₁₁),
L₄ is a phenyl group, a naphthyl group, or a pyridinyl group, each unsubstituted or substituted with deuterium, *—F, *—SO₃(Q₁₁), a C₁-C₁₀ alkyl group, a C₁-C₁₀ alkoxy group, a phenyl group, a naphthyl group, a pyridinyl group, or a combination thereof.

9. The etching composition of claim 1, wherein
the hypervalent iodine-containing compound is one of Compounds 1 to 10 below:

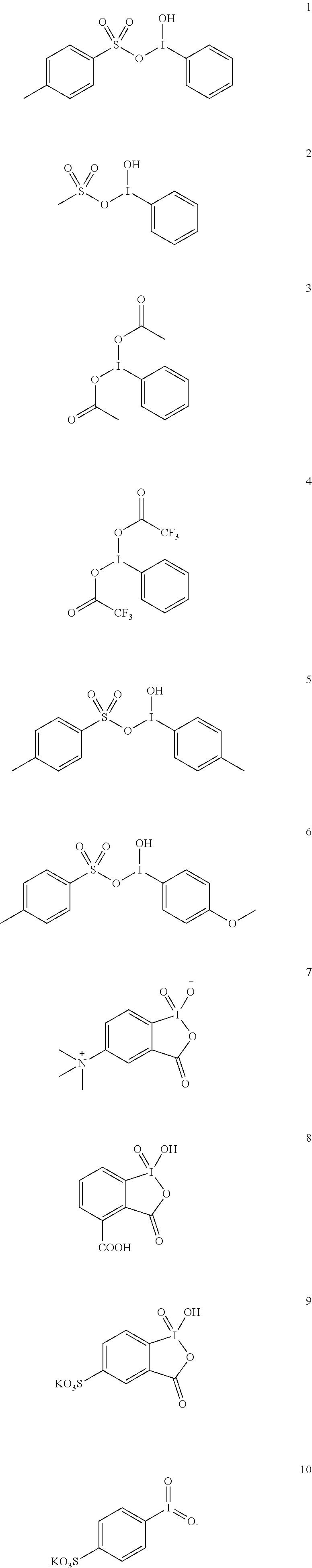

10. The etching composition of claim 1,
wherein an amount of the hypervalent iodine-containing compound is 0.005 wt % to 1 wt %, based on 100 wt % of the etching composition.

11. The etching composition of claim 2,
wherein the acid comprises a fluorine-based inorganic acid.

12. The etching composition of claim 2,
wherein the acid comprises hydrofluoric acid (HF), tetrafluoroboric acid, hexafluorosilicic acid, H₂ZrF₆, H₂TiF₆, HPF₆, or a combination thereof.

13. The etching composition of claim 2,
wherein an amount of the acid is 0.0001 wt % to 20 wt %, based on 100 wt % of the etching composition.

14. The etching composition of claim 1, further comprising a pH regulator.

15. The etching composition of claim 1,
wherein the etching composition has a pH of 0 to 4.0.

16. A method of etching a metal-containing layer, the method comprising:
preparing a substrate provided with a metal-containing layer; and
performing an etching process using the etching composition of claim 1 on the metal-containing layer to remove at least a portion of the metal-containing layer.

17. The method of claim 16,
wherein the metal-containing layer comprises indium (In), titanium (Ti), aluminum (AI), tungsten (W), lanthanum (La), scandium (Sc), gallium (Ga), zinc (Zn), hafnium (Hf), molybdenum (Mo), or a combination thereof.

18. The method of claim 16,
wherein the metal-containing layer comprises a first region and a second region,
a second etching rate at which the composition etches the second region is greater than a first etching rate at which the etching composition etches the first region, and
the etching process is performed by contacting at least a portion of the first region and at least a portion of the second region with the etching composition.

19. The method of claim 18,
wherein the first region comprises molybdenum, and
the second region comprises titanium nitride (TIN).

20. A method of manufacturing a semiconductor device, the method comprising:
preparing a substrate provided with a metal-containing layer;
performing an etching process using the etching composition of claim 1 on the metal-containing layer to remove at least a portion of the metal-containing layer; and
performing a subsequent manufacturing process(es) to manufacture a semiconductor device.
